(19) United States
(12) Patent Application Publication
(10) Pub. No.: US 2005/0087297 A1
(43) Pub. Date: Apr. 28, 2005

(54) Plasma processing apparatus and method for stabilizing inner wall of processing chamber

(76) Inventors: Hiroyuki Kitsunai, Ibaraki-ken (JP); Naoshi Itabashi, Tokyo (JP); Motohiko Yoshigai, Hikari-shi (JP); Tetsuo Ono, Tsukuba-shi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/912,177

(22) Filed: Aug. 6, 2004

(30) Foreign Application Priority Data
Aug. 6, 2003 (JP) 2003-206247
Jul. 20, 2004 (JP) 2004-212048

(51) Int. Cl. H01L 21/306

(52) U.S. Cl. 156/345.24

(57) ABSTRACT

The invention aims at providing a plasma processing apparatus capable of removing the deposition film in the processing chamber and suppressing the corrosion of wall surface material. The plasma processing apparatus for subjecting an object to be processed to vacuum processing by introducing a processing gas into a processing chamber 101 and generating plasma 110 comprises plasma generating means 106 through 108, a monitor means 112 for detecting the existence of a reaction product containing a material constituting an inner wall 102 of the processing chamber, and an alarm means for notifying that the existence of the reaction product containing the material constituting the inner wall 102 of the processing chamber has exceeded a predetermined amount, wherein a plasma cleaning is performed for every arbitrary etching process, and a wall surface stabilization process is subsequently performed using O₂ gas or F gas.

The present application is based on and claims priority of Japanese patent application No. 2003-206247 filed on Aug. 6, 2003 and No. 2004-212048 filed on Jul. 20, 2004, the entire contents of which are hereby incorporated by reference.

### FIELD OF THE INVENTION

The present invention relates to a plasma processing apparatus such as a plasma etching apparatus or a plasma CVD apparatus for etching or processing an object using plasma, and a plasma processing method.

### DESCRIPTION OF THE RELATED ART

In the fabrication process of a semiconductor apparatus, if a dust adheres to a substrate, it causes defect of the target device pattern and deteriorates the yield factor of the fabrication process. On the other hand, in a dry etching process in which various gases are introduced into the apparatus and etching is performed using the reaction of the introduced gas plasma, the reaction product generated by the etching adheres to the inner wall of the apparatus as deposition film and becomes the source of dusts.

Thus, it is necessary to periodically remove the deposition film. A method for removing such deposition film is proposed, wherein after performing dry etching of a film containing Al formed on the surface of a semiconductor substrate in a processing chamber using a chlorine-based gas, a mixed gas including gas containing O₂, gas containing F and gas containing Cl is introduced into the processing chamber, and plasma is generated by the mixed gas to remove the aluminum chlorine carbide (AlₓC_{y}Cl_{z}) which is the residual reaction product attached to the interior of the processing chamber, so as to cut down the maintenance time of the dry etching apparatus (refer for example to patent document 1).

Further, a method is proposed according to which after performing plasma cleaning, the wall surface of the etching chamber on which the deposition film is formed is slightly etched using plasma, in order to constantly maintain the status of the etching chamber (refer for example to patent document 2).

[Patent Document 1]

Japanese Patent Application Laid-Open No. 8-319586

[Patent Document 2]

Japanese Patent Application Laid-Open No. 7-335626

However, highly corrosive gases containing chlorine (Cl), hydrogen bromide (HBr) or the like are now used in the plasma etching process. Typically, the structural members in the processing chamber of the etching apparatus are formed of materials which are highly anticorrosive to these gases, such as a material provided with an oxide coating such as alumite (anodized aluminum) and alumina ceramic spray coating. On the contrary, if the deposition film is completely removed by plasma cleaning, even if the oxide coating has a stable structure, the surface layer may be corroded by the highly corrosive gas creating a state where particles are easily generated. Moreover, since the oxide coating has a porous structure, the gas may reach the base material on which the coating is formed, subjecting the base material to corrosion.

The above-mentioned prior art techniques characterized in either removing the deposition film or removing the surface layer of the wall after removing the deposition film, and they lack to consider the problem of corrosion of the surface layer of the wall surface material or the corrosion of the base member.

### SUMMARY OF THE INVENTION

The object of the present invention is to solve the above-mentioned problems by providing a processing apparatus capable of removing the deposition film on the inner surface of the processing chamber and suppressing corrosion of the wall surface material, and capable of carrying out a method or process of stabilizing the wall surface of the processing chamber.

The above object is achieved by providing a processing system capable of adding a stabilization process for stabilizing the wall surface of the processing chamber at an arbitrary timing to the operation process of the etching apparatus.

Moreover, the above object is achieved by providing to the etching apparatus an alarm means for notifying the occurrence of a corrosion by detecting the corrosion of the wall surface via a monitor means disposed in the processing chamber, and providing an operation means capable of carrying out the stabilization process step upon receiving a detection signal.

The method to be processed by the present apparatus comprises a stabilization process step provided during the transition from the plasma cleaning process to the etching process and preferably directly after the plasma cleaning process, for substituting corrosive gas molecules bonded to the inner material of the processing chamber using oxygen or fluorine (such as SF₆, CF₄, C₂F₆, CₓF_{y}) gas plasma.

Furthermore, the above-mentioned object is achieved by providing to the etching apparatus a function to arbitrarily select, set and input how many wafers are to be processed during continuous processing before the plasma cleaning process is performed, and how long the time for stabilization process will be.

### BRIEF DESCRIPTION OF THE DRAWINGS

FIG. 1 is a diagram showing the overall structure of a plasma processing apparatus based on which the present embodiment is described;

FIG. 2 is a wafer process flow of the prior art;

FIG. 3 is a schematic cross-sectional view of the wall surface material of the apparatus based on which an embodiment of the present invention is described;

FIG. 4 is a schematic cross-sectional view of the wall surface material of the apparatus based on which an embodiment of the present invention is described;

FIG. 5 shows an example of the monitor signals based on which an embodiment of the present invention is described;

FIG. 6 is a wafer process flow based on which an embodiment of the present invention is described;

FIG. 7 is a schematic cross-sectional view of the wall surface material of the apparatus based on which an embodiment of the present invention is described;

FIG. 8 is an example of the process results based on which the effects of the present invention are described;

FIG. 9 is an example of the process results based on which the effects of the present invention are described; and

FIG. 10 is an example of the process results based on which the effects of the present invention are described.

### DETAILED DESCRIPTION OF THE PREFERRED EMBODIMENT

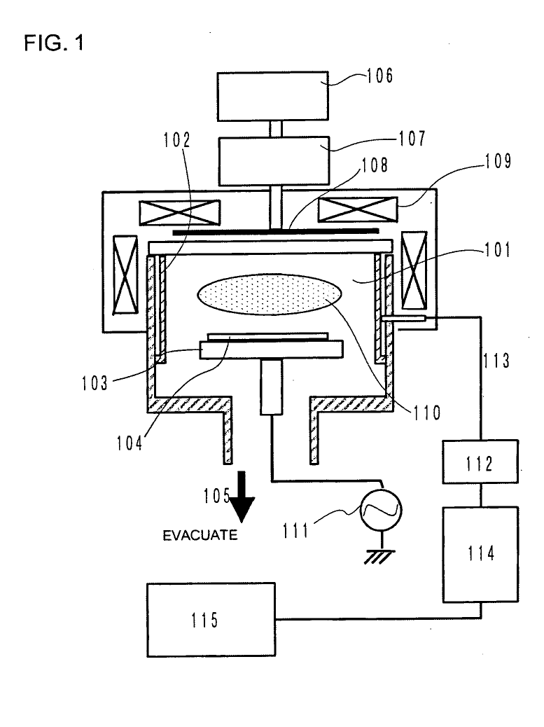

One preferred embodiment of the present invention will now be described with reference to the drawings. FIG. 1 shows a dry etching apparatus used to carry out the present invention, which is an example of an apparatus utilizing electron cyclotron resonance (ECR). In FIG. 1, the dry etching apparatus comprises an etching (processing) chamber 101, a wall surface 102 disposed within the etching chamber that comes into direct contact with plasma, a substrate stage 103 on which an Si substrate 104 to be subjected to etching is placed, and an evacuation port 105 for evacuating the interior of the processing chamber to a predetermined pressure. Further, the dry etching apparatus comprises a UHF-band electromagnetic power supply 106, a matching network 107, an antenna 108, a solenoid coil 109, an RF power supply 111, an emission spectrometer 112, an optical fiber 113 for sending the plasma emission into the emission spectrometer, a computer 114 for operating the emission spectrometer, and a computer 115 for controlling the whole etching apparatus.

Upon performing the etching process, the processing chamber is controlled to predetermined pressure via evacuation. Next, electromagnetic waves of the UHF band are introduced from the UHF-band electromagnetic power supply 106 via the matching network 107 and the antenna 108 into the etching chamber 101. The introduced electromagnetic waves resonate with the magnetic field formed via the solenoid coil 109 to generate plasma by the gas in the processing chamber, and the generated plasma 110 is used to perform the etching. The RF power supply 111 applies RF bias to the substrate stage 103 on which the substrate is placed so as to control the process contour, by which the ions in the plasma are attracted toward the substrate and anisotropic etching is performed.

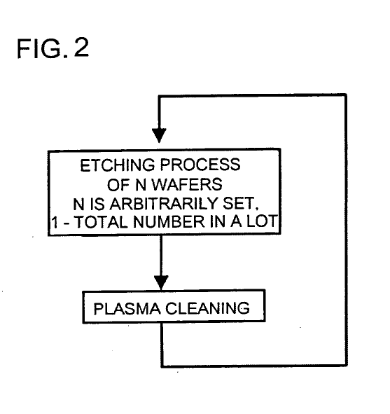

Next, the process flow for carrying out a surface treatment of a Si wafer using this apparatus is described with reference to FIG. 2. For example, in processing a gate electrode of a semiconductor device, a polycrystalline Si is etched by a plasma formed of a highly corrosive gas such as Cl₂ and HBr, or a mixture of such gases. Further, in addition to the above, the recent trend is to use much gas containing F, such as CF₄, since F has the highest reactivity to Si and thus the etching rate can be enhanced. After the etching is completed, plasma cleaning is performed using plasma generated from gas having high reactivity to Si, such as SF₆, aimed at preventing the reaction products of Si from depositing on the inner wall of the processing chamber 101 as deposition film after the etching and generating particles containing Si. In the past, plasma cleaning was normally performed between lots, but recently, the process accuracy requirement has become stricter and the atmosphere within the processing chamber is required to be maintained constant at all times, so now there are increasing number of cases where the plasma cleaning is performed per a given number “N” of substrates being processed (for example, N=5), or per every substrate being processed.

As described, F having high reactivity to Si is now also used during etching in addition to plasma cleaning in many cases, so there are fewer cases where deposits exist on the wall surface of the processing chamber during the sequential process flow shown in FIG. 2.

On the other hand, the interior of the processing chamber of the etching apparatus is generally formed of a material provided with an oxide coating having anticorrosive properties to the above gases. When even a very small amount of so-called heavy metal such as Fe and Cr adhere to the surface of the Si substrate, it will be diffused across the Si semiconductor and deteriorate the operation of the semiconductor. Therefore, it is especially common to use an aluminum-based oxide coating such as alumite (anodized aluminum) and alumina ceramics spray coating. The base material of the coating should preferably be light weight and have small specific gravity from the view point of workability. Thus, it is common to use an aluminum alloy. The aluminum alloy is used as the base material in many cases, even when a coating other than the above-mentioned aluminum-based coating is adopted.

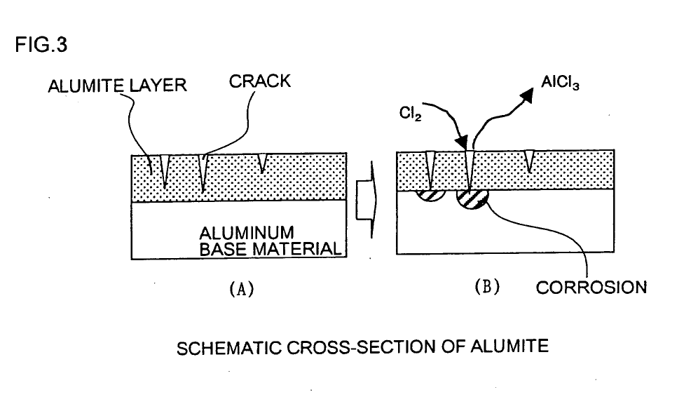

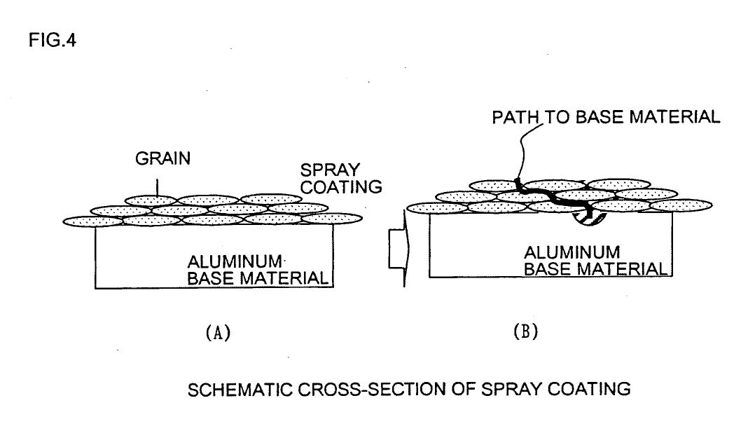

As described, when there are only few cases where deposits exist on the wall surface of the processing chamber during the process sequence, even the stable-structured oxide coating will have its surface layer corroded by the highly corrosive gas and may be in a state where particles easily occur. Furthermore, the oxide coating has a porous structure, and since the temperature thereof increases by the heat from the plasma, it is in an environment where cracks may be caused by thermal expansion. In other words, another problem occurs by the gas reaching and corroding the base material of the coating through the cracks or the pores in the coating. FIGS. 3 and 4 are schematic cross-sectional views showing the spray coating and the alumite coating. The aluminum used as the base material of the coating is corroded by Cl or HBr, and is released into the processing chamber as AlCl₃ or AlBr, so the drawback caused by the corrosion is significant, both from the viewpoint of life of the processing chamber inner wall and the viewpoint of influence to the etching results.

According to the present embodiment, the etching apparatus is equipped with a monitor means for detecting the existence of a reaction product containing the material forming the wall surface of the processing chamber, and a means for generating an alarm when the concentration of the reaction product exceeds a predetermined amount during the sequence of process flow. Thereby, it becomes possible to prevent the defective etching result caused by AlCl₃ or AlBr from occurring. It also provides an indication of the timing for replacing parts. According to the present embodiment, a plasma emission spectrometer is illustrated as an example of the monitor means. In FIG. 1, reference number 112 shows the emission spectrometer, 113 shows the optical fiber for taking in the plasma emission into the emission spectrometer, 114 shows the computer for operating the emission spectrometer, and 115 shows the computer for controlling the whole etching apparatus. It is possible to set in advance a signal indicating the reaction product containing the material constituting the wall surface of the processing chamber and a threshold of the signal in the computer 115 for controlling the etching apparatus, so that an alarm is activated when the threshold is exceeded based on the emission data sent thereto from the computer 114 for controlling the emission spectrometer. This process will be described in detail below.

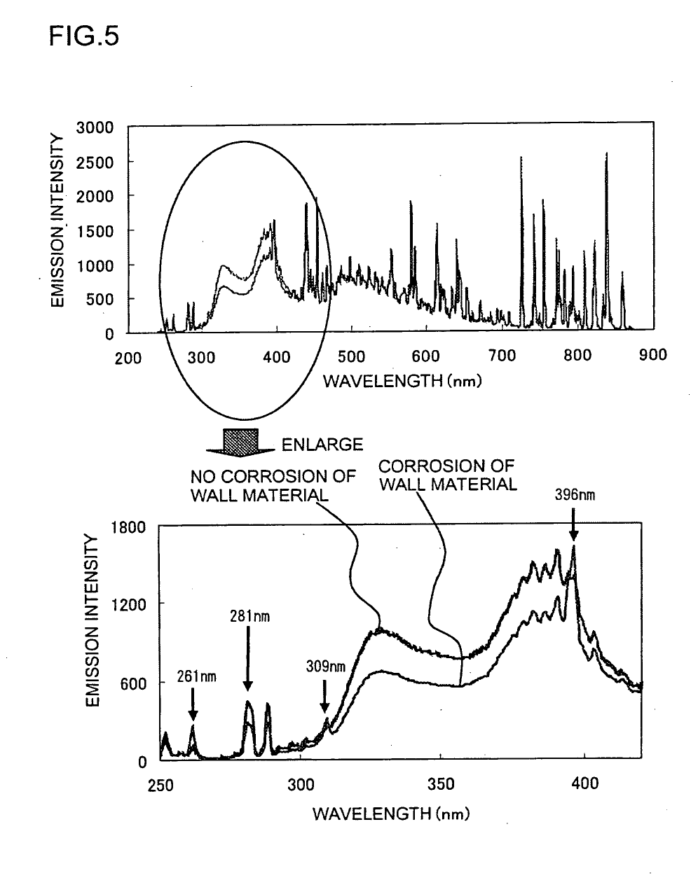

FIG. 5 shows a plasma emission spectrum obtained during a period of time while etching a polysilicon using Cl₂ gas plasma. The emission spectrum can be achieved by dividing a certain wavelength range, which in this example is from 250 nm to 850 nm, into plural channels (2000 channels in this example), and showing the emission intensity of each channel. Here, in detecting the reaction product containing the material constituting the wall surface of the processing chamber, the signal to be detected changes according to the combination of the gas used for the process and the material of the wall surface of the processing chamber, so the present embodiment is equipped with a function to select the channel of the detection signal arbitrarily. The computer 115 for controlling the etching apparatus is set to generate an alarm signal when the signal of the specifically selected wavelength exceeds a threshold that can also be set arbitrarily.

For example, in order to detect corrosion of an Al member as according to the present embodiment, the emission of Al atoms, which is 396 nm, should be selected. The effectiveness can be further enhanced by providing a calculation function, for selecting plural signals, adding, subtracting, multiplying or dividing the same, and setting the result of the calculation as the detection signal. For instance, according to the example of FIG. 5, in order to detect Al, the emission of Al atoms can be observed at 309 nm in addition to 396 nm. Therefore, a stronger signal can be obtained by adding the signals of 309 nm and 396 nm. According further to the example of FIG. 5, the etching of polysilicon proceeds by the reaction Si+Cl→SiCl (281 nm). However, when the Al of the wall surface is eaten away, the reaction Al+Cl AlCl (261 nm) simultaneously proceeds. In other words, the Cl radicals used in etching silicon is consumed by Al, by which the emission signal of SiCl of 281 nm is reduced. Therefore, a signal having higher S/N can be achieved by setting as the detection signal the result of adding the signal intensity of Al (309 nm and 396 nm) and the signal intensity of AlCl (261 nm), or the result of dividing the added signal intensity of Al and AlCl by the signal intensity of SiCl. Whether to select a combination of such signals depends on the combination of the gas used in the process and the wall surface material of the processing chamber, so it is important that the device is equipped with a function to select the detection signals arbitrarily.

Apart from the present embodiment., the same effects can be achieved using a gas mass spectrograph, an impedance monitor, or a detector for detecting the voltage or current of the plasma current.

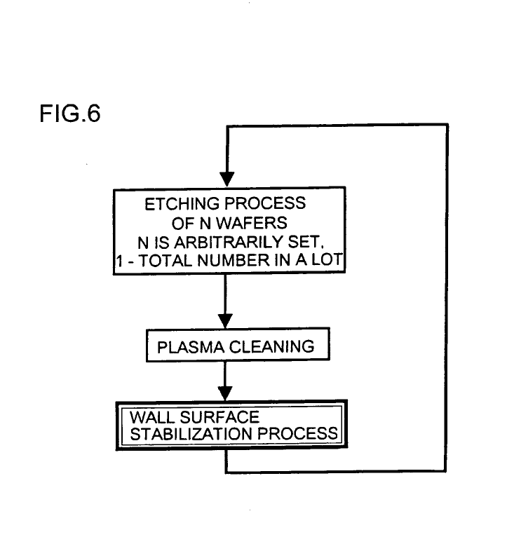

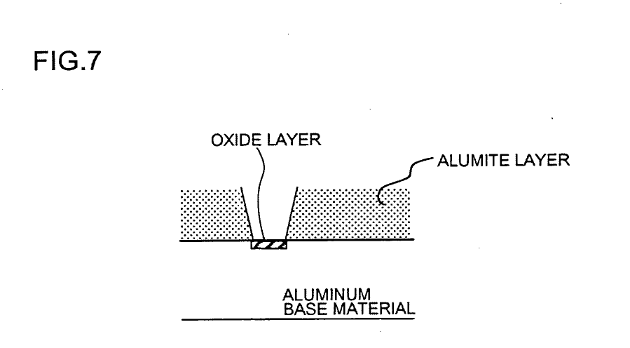

Next, another embodiment of the present invention will be explained. The present embodiment provides in the process flow sequence a stabilization process step for substituting corrosive gas molecules bonded to the inner material of the processing chamber during the transition from the cleaning process to the etching process. The process flow according to the present embodiment is shown in FIG. 6. Plasma discharge of gas that can become a compound having anticorrosive property to Cl₂ or HBr is performed as the stabilization process. Possible examples are O₂ or F with respect to aluminum-based materials. FIG. 7 is a schematic cross-sectional view, and as shown, it becomes possible to maintain anticorrosive property by forming an oxide layer or a fluoride layer at the bottom face of the crack. The oxide layer or the fluoride layer formed as illustrated on the surface via the gas plasma is considered to be very thin, on the order of a few nm, but the occurrence of aluminum corrosion can be prevented for a long period of time by performing the stabilization process again before the oxide layer or fluoride layer is gone.

[Experiment 1]

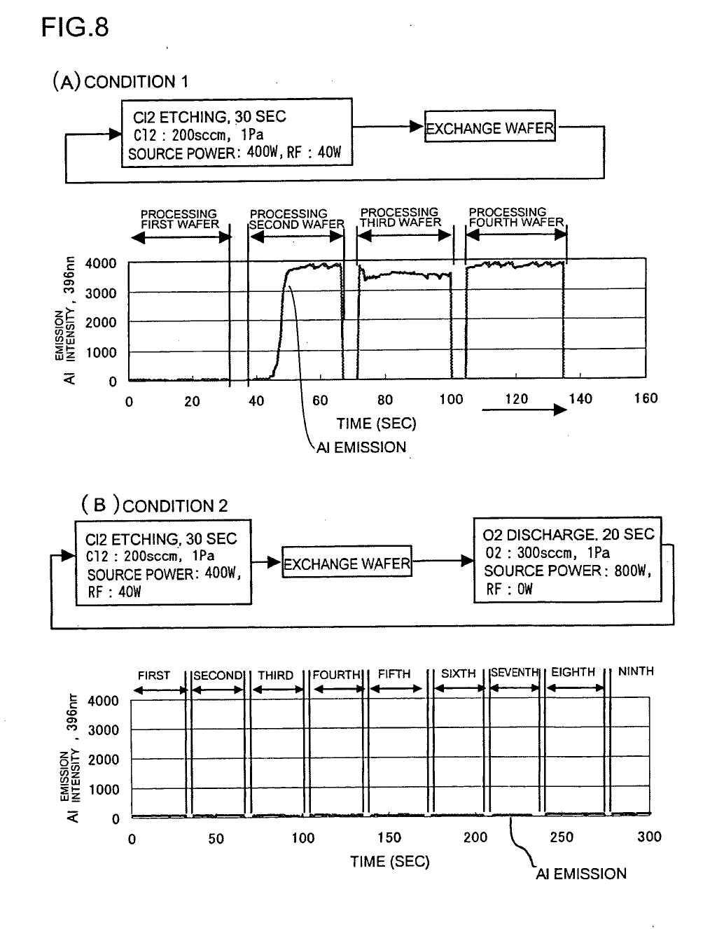

By the experiments carried out by the present inventors, it has been discovered that the present invention is effective even when an ordinary anticorrosive aluminum was used in the inner wall surface of the processing chamber. FIG. 8 shows the results of the experiments. According to the experiments, the material of the inner wall surface of the processing chamber was A5051 anticorrosive aluminum, and the etching of an SiO₂ wafer was performed. The SiO₂ wafer was selected to cut the influence of Si reaction products on the deposition film. According to condition 1, etching was repeatedly performed using Cl₂ gas for 30 seconds. Etching was performed with 200 sccm Cl₂ gas flow rate, 1 Pa pressure, 400 W source power, and 40 W RF bias. According to condition 2, 20 seconds of O₂ gas plasma discharge was performed before etching, and the O₂ gas discharge and etching were repeatedly performed. The O₂ gas discharge was performed with 300 sccm O₂ gas flow rate, 1 Pa pressure, 800 W source power, and 0 W RF bias. The experiments were performed while monitoring the Al emission wavelength 396 nm through the plasma emission spectrometer attached to the processing chamber, and according to condition 1 where O₂ discharge was not performed, significant emission of Al was observed during the processing of a second wafer, whereas according to condition 2, there was no emission of Al recognized even after processing more than 10 wafers. It was clearly recognized that the wall surface material was protected by forming the oxidation layer constantly on the surface.

[Experiment 2]

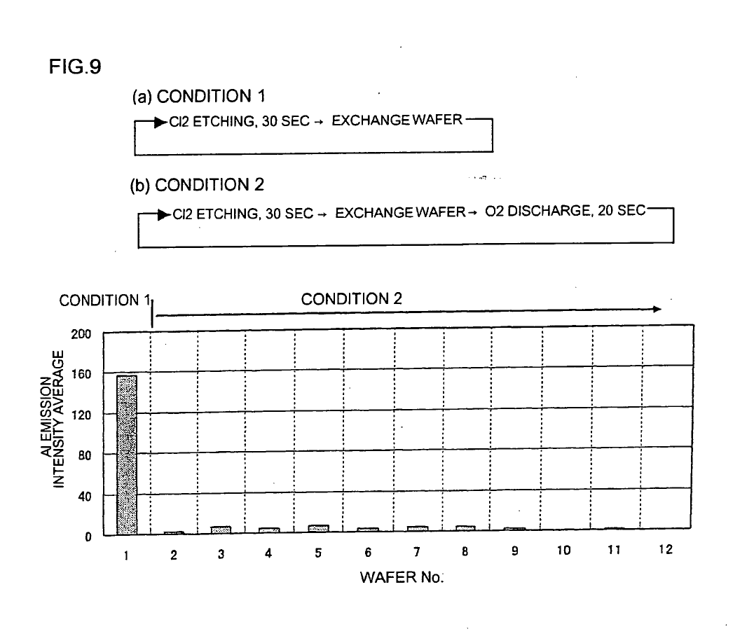

FIG. 9 shows the result of experiments performed using a wall surface material with alumite (anodized aluminum) processing. The experiments were performed using a wall material having been used for over a year and with the alumite eaten away at some areas exposing the base material. In the experiments, Si was etched using Cl₂ gas. According to condition 1, after performing cleaning, 60 seconds of Si etching was repeatedly performed, and according to condition 2, 20 seconds of O₂ gas plasma discharge was performed before the etching. The experiments were performed while monitoring the Al emission wavelength 396 nm via the plasma emission spectrometer attached to the processing chamber, and according to condition 1, the emission of Al was already observed during the processing of the second wafer, whereas according to condition 2, there was no emission of Al observed even after processing 25 wafers.

Thus, by providing a stabilization step between the cleaning step and the etching step so as to constantly carry out the stabilization process for forming an oxidation layer or a fluoride layer on the surface of the chamber via gas plasma, it becomes possible to prevent the occurrence of aluminum corrosion, in other words, the wasting of the wall surface material. Therefore, by providing to the etching apparatus, possibly to the computer for controlling the apparatus, a function to set up the discharge conditions of the stabilization step and to perform the stabilization between the cleaning process and the etching process, it becomes possible to stably operate the apparatus for a long period of time while preventing the corrosion of the wall surface of the apparatus.

The above embodiment was described according to an example in which the stabilization step was performed after each plasma cleaning step, but there is no need to perform the stabilization step for each plasma cleaning step, and the stabilization step can be performed at any arbitrary timing. In other words, the effectiveness of the present invention is further enhanced by providing to the etching apparatus a function to set the timing for performing the stabilization process arbitrarily. For example, not only the products having the same device structure are always processed in a single processing chamber, but the processing of various products having different film thicknesses, different film qualities and different mask areas are normally performed. In other words, the etching conditions such as the gas pressure, the gas flow rate and the supplied power differ with every product, and the degree of influence on the wall surface of the apparatus differs according to conditions. Therefore, the safest apparatus operation would be to perform the stabilization step per every cleaning step performed in the processing of any product. However, if the stabilization step is performed per every cleaning step according to even the conditions having only a small influence of corrosion to the wall surface of the apparatus, the actual operating time during which the apparatus is used for actual product processing is oppressed. Thus, by determining for every product the interval of the stabilization process, for example, if product A is processed under conditions having extremely strong corrosiveness, setting the stabilization step to be performed per every plasma cleaning, if product B has smaller influence than product A, setting the stabilization step to be performed once every four lots of processing, and if product C has even smaller influence, setting the stabilization step to be performed once every eight lots of processing, the deterioration of the actual operation time of the apparatus can be suppressed to a minimum while the corrosion of the wall surface is prevented for a long period of time.

The interval for performing the stabilization process was described above, but the anticorrosive effect and the throughput of the apparatus can both be satisfied similarly by changing the period of time of the stabilization process per product, that is, by performing a short stabilization process for products processed under conditions having small corrosive impact on the wall surface of the apparatus and by performing a longer stabilization process for products processed under conditions having stronger corrosive impact. Moreover, both the time and the interval of the stabilization process can be varied. It is important that the apparatus is equipped with a function to set to the computer for controlling the processing apparatus the timing and the period of time for performing the stabilization process for each product.

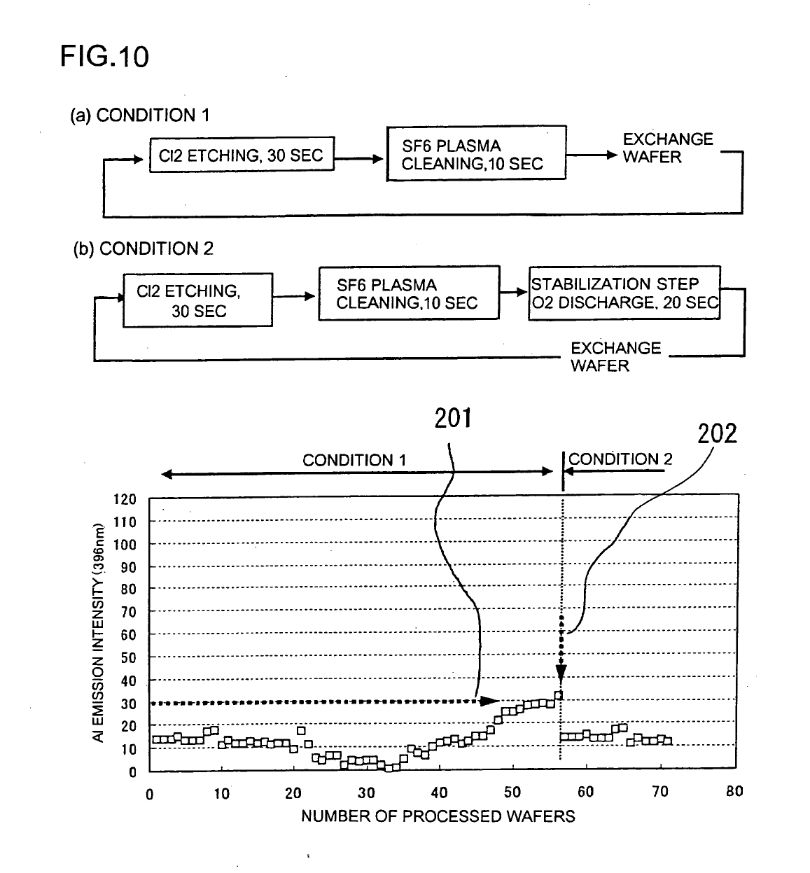

Next, another embodiment of the present invention will be described with reference to FIG. 10. The present embodiment characterizes in that a monitor means for detecting the emission of wall material to the plasma is provided to detect the corrosion of the interior member of the processing chamber via the monitor means and performing the wall surface stabilization process.

The monitor means can be, as shown in the first embodiment, a spectrometer for detecting the emission from the plasma. The emission spectrometer can be a detector for taking out a single wavelength emission such as a monochromator, but it is preferably a detector capable of outputting multiple signals such as a spectrometer that outputs wavelength-decomposed emission spectrum. Moreover, it can be a mass spectrograph capable of monitoring the gas in the processing chamber per mass numbers. Furthermore, detection is possible through use of a current detector or a voltage detector, a current-voltage phase difference detector, a traveling wave detector or a reflected wave detector or an impedance monitor of the power, disposed in the path for supplying power to the plasma generating means. The status of the inner wall extremely sensitively affects the impedance of plasma. The above-mentioned monitors disposed in the power path for plasma generation have very high sensitivity, capable of detecting even a subtle corrosion of the wall. The monitor means outputs a signal either every predetermined period of time or every sampling time determined in advance. Here, the embodiment is explained using the plasma emission spectrometer similar to the first embodiment.

### [Experiment 3]

FIG. 10 shows the results of applying to the apparatus a wall surface material with alumite processing. The present invention was applied to the apparatus whose wall surface material 102 has been used over a year and almost ready for replacement. The experiments were conducted using Cl₂ gas under the same conditions as experiment 1 to etch an Si bare wafer. In order to remove the deposition film of Si, plasma cleaning was performed for 10 seconds per each wafer using SF₆ plasma without a dummy wafer. A plasma emission spectrometer was attached to the processing chamber to monitor the Al emission wavelength 396 nm while performing etching, and the average value of emission wavelength 396 nm during etching was output. The sampling was performed once every second.

First, continuous processing was performed according to condition 1 without the stabilization step, and when the value exceeded a maximum value set in advance, the processing was performed according to condition 2 with the stabilization step. It was confirmed after continuously processing 10 wafers that the emission intensity of wavelength 396 nm showed stable transition between 10 and 20, so the maximum value of the emission intensity was set to 30 (reference number 201 in the drawing). The value started to rise gradually when approximately 45 wafers were processed, and exceeded the maximum value at the 56th wafer (202 in the drawing), so the processing condition was switched to condition 2 in which the stabilization step is performed after the plasma cleaning step, and it was confirmed that the emission intensity of wavelength 396 nm was reduced to the level when the continuous processing was started. Thus, by carrying out the stabilization step automatically based on the Al discharge detection signal from the monitor, it becomes possible to effectively prevent corrosion of the wall surface while suppressing the deterioration of operation efficiency. Moreover, if there is still a possibility of Al discharge during long term processing even by performing the stabilization process, it is desirable to set up in advance a certain extension time, and automatically carry out the time extension of the stabilization step upon receiving the Al discharge detection signal from the monitor. For example, in FIG. 10 the stabilization step S is set to 20 seconds, but by extending the same to 30 seconds when the threshold is exceeded for the second time, to 40 seconds when the threshold is exceeded for the third time and so on, it becomes possible to effectively achieve the wall surface stabilization. Here, the time was increased for ten seconds each, but the degree of corrosion of the wall surface depends on the plasma power and processing time of the plasma processing being performed, so it is preferable to enable the extension time to be set arbitrarily in the apparatus. According to the present embodiment, the average value of the emission intensity was used as the monitor data, but it is also possible to use the maximum intensity monitored during etching as the monitor data.

By providing to the etching apparatus a monitor means for detecting the corrosion of the inner wall surface of the processing chamber, an alarm means for notifying the occurrence of corrosion, a control means for performing the stabilization process upon receiving the detection signal, and a means for setting up the timing for performing the stabilization step, the duration time thereof and the extension time thereof, for example, stable continuous fabrication becomes possible.

The detection of Al emission through the monitor means according to the present embodiment is effective from the viewpoint of apparatus management. When a notice is output in case the monitored value exceeds a threshold value set up in advance, the operator can be notified of the status of the apparatus. The output can be an alarm such as a buzzer, a display on the operation panel, or a display on the screen of a personal computer of the operator.

Even with the stabilization step performed constantly, the base material is easily corroded if the surface coating such as alumite or spray coating becomes too thin or is partially wasted, and the alarm will be output frequently. It is also effective to vary the level of the warning by how many times the threshold value is exceeded continuously or by the total number of warnings being output. For example, according to one possible application, if the threshold value is exceeded once but not in the next processing, a minor warning is output and processing is continued, but if the threshold value is exceeded three times in a row or if the total number of times the threshold value is exceeded has exceeded a predetermined value, for example, it is possible to prohibit processing and to perform maintenance. Furthermore, if the wall surface stabilization is to be achieved by extending the stabilization process time when the threshold value is exceeded, another possible application would be to determine the maximum extension time and when the maximum time is exceeded, to judge that the stabilization is not possible, to output a warning to replace the parts and to perform maintenance. According to these applications, by performing maintenance such as the cleaning of the apparatus, it becomes possible to prevent in advance the occurrence of the cause of defects such as the contamination of the wafer being processed or the adhesion of particles.

According to the above embodiments, the inner wall of the processing chamber was formed of an aluminum base member having an alumite layer or a ceramic layer formed to the surface thereof, and O₂ gas was used as the wall surface protection gas, but the present invention is not limited to such examples. The inner wall member of the processing chamber can be provided with any oxide ceramic coating to achieve the objects of the present invention. Moreover, when a fluoride ceramic coating is provided, F-based gas should be used as the wall surface protection gas to achieve the objects of the present invention.

As described above, the present invention provides a plasma processing apparatus for subjecting an object to be processed to vacuum treatment by introducing processing gas into a processing chamber and generating plasma, the apparatus comprising a plasma generation means, a monitor means for detecting the existence of a reaction product containing a material constituting an inner wall of the processing chamber, and an alarm means for notifying that the existence of the reaction product containing the material constituting the inner wall of the processing chamber exceeded a certain amount. Furthermore, the above monitor means is any of or a combination of the following: a plasma emission spectrometer, a mass spectrograph or an impedance monitor detecting means disposed in the plasma processing chamber, a current detector or a voltage detector or a current-voltage phase detector disposed in the path for supplying power to the plasma generating means, a traveling wave detector or a reflected wave detector of power.

The present invention is equipped with a means having a function to select an arbitrary signal out of the plural signals obtained through the monitor means that can be detected via the monitor as a detection signal for indicating the existence of a reaction product containing the material constituting the inner wall of the processing chamber and to arbitrarily set up the threshold of the signal value for generating an alarm, and a calculation function to select two or more signals from the plural signals obtained through the monitor means and performing one or a combination of the following calculations: adding, subtracting, multiplying and dividing; to the signals and setting the result of calculation as the detection signal.

The present invention provides a plasma processing apparatus for subjecting an object to be processed to vacuum treatment by introducing processing gas into a processing chamber in which the object is placed and generating plasma, wherein the apparatus is equipped with a function to set up an etching step, a plasma cleaning step and a wall surface stabilization step for protecting the inner wall of the processing chamber, and to set up the order and frequency of each step arbitrarily.

Moreover, the present invention provides a method for stabilizing the inner wall surface of a processing chamber in a plasma processing apparatus for subjecting an object to be processed to vacuum treatment by introducing processing gas into the processing chamber in which the object is placed and generating plasma, characterized in performing a wall surface stabilization process in which an inner wall protection gas for protecting the inner wall surface of the processing chamber is introduced and plasma processing is performed, after performing a plasma cleaning process in succession to an etching process. Moreover, according to the present invention, the above method for stabilizing the inner wall surface of a processing chamber in a plasma processing apparatus characterizes in that the inner wall protection gas contains oxygen (O₂) gas or fluorine-based (F) gas, and that the flow ratio of oxygen (O₂) gas or fluorine-based (F) gas to the total gas flow is more than at least 50%.

According further to the present invention, the plasma processing apparatus is equipped with a function to execute the wall surface stabilization step set up in advance when receiving a signal generated by the monitor means in the processing chamber indicating the increase of reaction product containing the material constituting the inner wall of the processing chamber. Moreover, it is equipped with a function to extend for a predetermined time the time set up in advance to execute the wall surface stabilization step according to the total number of signals generated by the monitor means indicating the increase of reaction product containing the material constituting the inner wall of the processing chamber.

1. A plasma processing apparatus for subjecting an object to be processed to vacuum processing by introducing processing gas into a processing chamber and generating plasma, the apparatus comprising:
a plasma generating means;
a monitor means for detecting the existence of a reaction product containing a material constituting an inner wall of the processing chamber; and
an alarm means for notifying that the existence of the reaction product containing the material constituting the inner wall of the processing chamber has exceeded a predetermined amount.

2. The plasma processing apparatus according to claim 1, wherein the monitor means is any one or a combination of the following:
a plasma emission spectrometer, a mass spectrograph or an impedance monitor detector disposed in the plasma processing chamber, a current detector, a voltage detector or a current-voltage phase detector disposed in a path for supplying power to the plasma generating means, a traveling wave detector or a reflected wave detector of power.

3. The plasma processing apparatus according to claim 2, wherein the apparatus further comprises,
a means having a function to select an arbitrary signal out of the plural signals detectable by the monitor and output from the monitor means as a detection signal indicating the existence of the reaction product containing the material constituting the inner wall of the processing chamber, and to arbitrary set a threshold value for the signal value based on which the alarm is to be output.

4. The plasma processing apparatus according to claim 3, wherein the apparatus further comprises a calculation function for selecting two or more signals out of the plural signals output from the monitor means; subjecting the signals to any one or a combination of the following calculations: adding, subtracting, multiplying and dividing; and setting the calculated result as the detection signal.

5. A plasma processing apparatus for subjecting an object to be processed to vacuum processing by introducing processing gas into a processing chamber in which the object is placed and generating plasma, the apparatus comprising:
a function for setting up an etching step, a plasma cleaning step, and a wall surface stabilization step for protecting an inner wall of the processing chamber, wherein the order and frequency of each step can be set arbitrarily.

6. A method for stabilizing an inner wall surface of a processing chamber in a plasma processing apparatus for subjecting an object to be processed to vacuum processing by introducing processing gas into the processing chamber in which the object is placed and generating plasma, the method comprising:
after performing a plasma cleaning process in succession to an etching process, a wall surface stabilization process is performed in which an inner wall protection gas for protecting the inner wall surface of the processing chamber is introduced and plasma processing is performed.

7. The method for stabilizing an inner wall surface of a processing chamber in a plasma processing apparatus according to claim 6, wherein
the inner wall protection gas contains either an oxygen (O₂) gas or a fluorine-based (F) gas, and the ratio of flow rate of the Oxygen (O₂) gas or fluorine-based (F) gas to the total gas flow rate is at least more than 50%.

8. The plasma processing apparatus according to claim 5, wherein the apparatus further comprises:
a function to carry out a wall surface stabilization process step set up in advance upon receiving a signal indicating an increase in the reaction product containing the material constituting the inner wall of the processing chamber output from the monitor means in the processing chamber according to claims 1 through 4.

9. The plasma processing apparatus according to claim 8, wherein the apparatus further comprises:
a function to extend for a predetermined time the time for carrying out the wall surface stabilization process step set up in advance in response to a total number of signals received indicating an increase in the reaction product containing the material constituting the inner wall of the processing chamber output from the monitor means in the processing chamber according to claims 1 through 4.
